(19) United States
(12) Patent Application Publication
(10) Pub. No.: US 2026/0227823 A1
(43) Pub. Date: Aug. 6, 2026

(54) TIMER CIRCUIT

(71) Applicant: STMicroelectronics International N.V., Geneva (CH)

(72) Inventor: Mark TRIMMER, Coublevie (FR)

(73) Assignee: STMicroelectronics International N.V., Geneva (CH)

(21) Appl. No.: 19/463,743

(22) Filed: Jan. 29, 2026

(30) Foreign Application Priority Data
Jan. 31, 2025 (FR) FR2501006

(51) Int. Cl. G06F 1/14; G06F 9/30

(52) U.S. Cl. CPC G06F 1/14; G06F 9/30101

(57) ABSTRACT

A timer circuit includes a register configured to be synchronized on a clock signal and to store a number as an X-bit signed integer, X being greater than two. At each cycle of the clock signal, the timer circuit decrements the number stored in the register by one if the number has a value different from a maximal value and from a minimal value that the number is able to take. At each cycle of the clock signal, the timer circuit keeps the number stored in the register unchanged if the number has a value equal to the maximal value or to the minimal value.

### PRIORITY CLAIM

This application claims the priority benefit of French Application for Patent No. FR2501006 filed on January 31, 2025, the content of which is hereby incorporated by reference in its entirety to the maximum extent allowable by law.

### TECHNICAL FIELD

The present disclosure relates generally to electronic circuits, for example, integrated electronic circuits, and, more particularly, to timer circuits.

### BACKGROUND

Timer circuits are widely used in electronic circuits and systems, for example in microprocessors.

Timer circuits are widely used in electronic circuits and systems, for example, in microprocessors. Among known timer circuits, the present disclosure more specifically relates to countdown timer circuits. A countdown timer circuit is configured to count down from an initial value programmed into the timer circuit until the value stored in the timer circuit reaches zero, with the countdown implemented by decrementing the value stored in the timer at each cycle of a clock signal.

A countdown timer circuit generally needs to implement several functionalities. For example, when the countdown timer circuit reaches zero, an alarm must be asserted or activated. When an alarm is asserted by the timer circuit, the timer circuit is configured so that the alarm can be cleared by another circuit or by a user. The countdown timer circuit can be programmed by a user or another circuit with an initial value from which the timer circuit counts down, in order to configure the time (the number of clock cycles) to be counted by the timer circuit until it reaches zero. The countdown timer circuit can be disabled by another circuit or a user, so that the timer circuit stops counting down. The timer circuit can be enabled or started, in order to set the time instant from which the countdown timer circuit begins to count down. The timer circuit can provide an indication of the time (the number of clock cycles) that is left until the timer reaches zero. The timer circuit can also provide an indication of the time (the number of clock cycles) that has elapsed since the timer reached zero.

To implement these functionalities, a countdown timer circuit generally comprises a register that stores the current value of the timer circuit. When the timer circuit is counting down, the current value stored in the timer circuit is decremented by one at each clock cycle. The timer circuit generally comprises additional registers to store the current state of an enabling signal that indicates whether the timer circuit is enabled and should count down or is disabled, and/or the current state of an alarm signal, and/or to store an initial programming value of the timer circuit, and/or to store the time that has elapsed since the timer circuit reached zero, and/or to store the time that is left until the timer will reach zero.

The provision of multiple registers in a timer circuit results in complex circuits. Furthermore, in known countdown timer circuits, more than one clock cycle is needed to program an initial value into the timer circuit and to start the timer circuit, which can be an issue in applications where atomic operations are needed and where it is required that programming the timer circuit and enabling it to count down are implemented in only one clock cycle.

### SUMMARY

There is a need to address all or part of the drawbacks of known countdown timer circuits.

One embodiment provides a timer circuit comprising a register configured to be synchronized to a clock signal and to store a number as an X-bit signed integer, where X is strictly greater than two, wherein the timer circuit is configured, at each cycle of the clock signal:

to decrement by one the number stored in the register if the number has a value different from the maximum value that the number can take and from the minimum value that the number can take, and

to keep unchanged the number stored in the register if the number has a value equal to the maximum value or to the minimum value.

In one embodiment, the maximum value is equal to 2^{(X-1)} - 1 and the minimum value is equal to -2^{(X-1)}.

In one embodiment, the timer circuit is configured, when receiving a write request for a programming value, to write the programming value into the register.

In one embodiment, the timer circuit is configured so that writing the programming value into the register has priority over decrementing the number stored in the register.

In one embodiment, a bit indicating the sign of the number stored in the register implements an alarm signal.

In one embodiment, X is equal to 32.

In one embodiment, the register is configured to store only X bits.

In one embodiment, the timer circuit comprises no additional registers.

In one embodiment, the timer circuit is configured so that the number stored in the register has the maximum value when the timer circuit is reset.

In one embodiment, the timer circuit is a countdown timer circuit.

In one embodiment, the register of the timer circuit is configured to be read.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 illustrates, schematically and in block form, an embodiment of a countdown timer circuit; and

FIG. 2 illustrates, by a flow chart, the operation of the countdown timer circuit of FIG. 1.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, the usual electronic systems or applications in which a countdown timer circuit may be provided were not detailed in the present disclosure, the described embodiments of countdown timer circuit being compatible with these usual systems and applications.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms "front", "back", "top", "bottom", "left", "right", etc., or to relative positional qualifiers, such as the terms "above", "below", "higher", "lower", etc., or to qualifiers of orientation, such as "horizontal", "vertical", etc., reference is made to the orientation shown in the figures.

Unless specified otherwise, the expressions "around", "approximately", “substantially” and "in the order of" signify within 10 % or 10°, and preferably within 5 % or 5°.

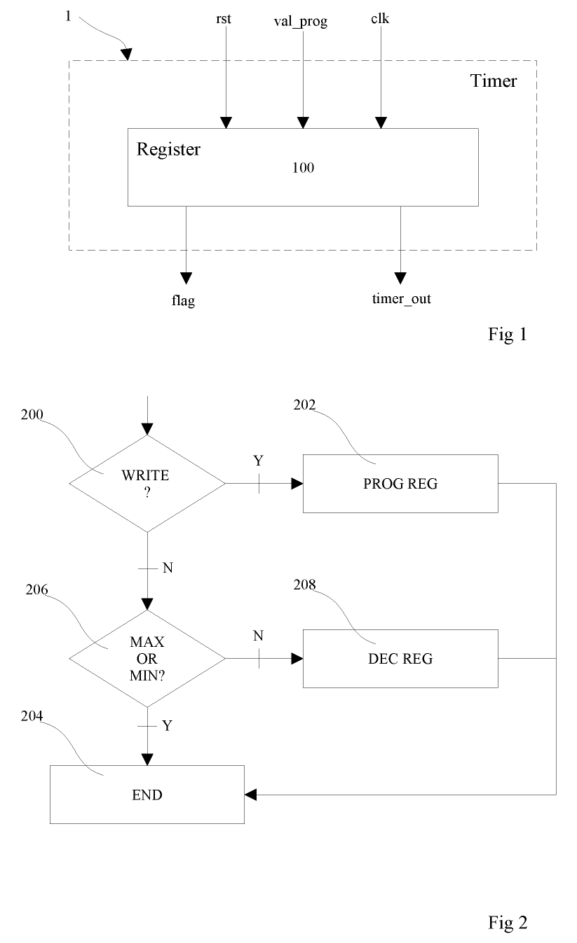

FIG. 1 illustrates, schematically and in block form, an embodiment of a countdown timer circuit 1.

The circuit 1 comprises a register 100. The register 100 is synchronized to a clock signal clk. In other words, the bits stored in the register 100 can be updated only in synchronism with the signal clk, for example, in synchronism with a given type of edge of the signal clk, preferably the rising edge.

The register 100 is configured to store a number as an X-bit signed integer, where X is strictly greater than two, for example, equal to thirty-two. Thus, the number stored in the register 100 has a value in the range from valmin to valmax, with valmin equal to -2^{(X-1)}, and valmax equal to 2^{(X-1)} - 1. For example, when X is equal to 8, valmin = -128 and valmax = 127.

The register 100 is configured to store only X bits. In other words, the register 100 is configured to store only the X-bit signed integer number. For example, the register 100 comprises exactly X flip-flops synchronized to the clock signal clk.

The register 100 is the only register of the timer circuit 1. In other words, the circuit 1 does not comprise any register other than register 100.

At each cycle of the signal clk, for example, at the beginning of each period of the signal clk, the circuit 1 is configured to operate as follows: when the number stored in register 100 has a value equal to valmax, the circuit 1 does not change the value of the number stored in register 100, or, in other words, the circuit 1 controls register 100 to keep the number stored in the register at its current value valmax; when the number stored in register 100 has a value different from the maximum value valmax and from the minimum value valmin, the circuit 1 is configured to decrement by one the value of the number stored in register 100; and when the number stored in register 100 has a value equal to valmin, the circuit 1 does not change the value of the number stored in register 100, or, in other words, the circuit 1 controls register 100 to keep the number stored in the register at its current value valmin.

For example, the circuit 1 is configured to receive a signal rst controlling the resetting of circuit 1. The timer circuit 1 is configured so that the number stored in register 100 when circuit 1 is reset, that is, at the end of a reset of circuit 1, has a value equal to valmax.

It follows that, after a reset of circuit 1, as the number stored in the register has the value valmax, the circuit 1 does not count down, or, in other words, is disabled.

The circuit 1 is configured to be programmed with a programming value val_prog. In other words, when circuit 1 receives a write request for the value val_prog, circuit 1 writes this programming value val_prog into register 100. In other words, when circuit 1 receives a write request for the value val_prog, circuit 1 updates the value of the number stored in register 100 with the value val_prog.

When circuit 1, and, more particularly, its register 100, is programmed with a value val_prog different from valmax and valmin, circuit 1 will count down by decrementing by one, at each cycle of the signal clk, the value of the number stored in register 100. In other words, circuit 1 is enabled.

Thus, when circuit 1 is programmed, or written, with a programming value val_prog positive and different from valmax, at each subsequent cycle of the signal clk, circuit 1 decrements by one the value of the number stored in register 100 until this value is equal to valmin. In particular, when the value of the number stored in register 100 goes from 0 to -1, the bit indicating the sign (polarity) of the value of the number stored in register 100 goes from the binary state '0' to the binary state '1', and will remain at the binary state '1' until circuit 1 is reset or programmed with a positive value val_prog.

It takes val_prog clock cycles for circuit 1, from the clock cycle when a positive value val_prog different from valmax is written into register 100, to the clock cycle when the number stored in the register becomes zero. Thus, programming timer circuit 1 with a positive programming value val_prog different from valmax allows the use of circuit 1 as a countdown timer circuit that counts down for val_prog clock cycles.

Furthermore, using the bit indicating the sign of the value stored in register 100 as an alarm signal flag allows circuit 1 to indicate when it has finished counting down from a positive value val_prog different from valmax to zero, or, in other words, to indicate when circuit 1 has finished counting down for val_prog clock cycles.

Furthermore, when the signal flag indicates an active alarm, resetting circuit 1 or programming circuit 1 with a positive value val_prog allows clearing the alarm, or, in other words, deactivating the alarm.

Furthermore, when circuit 1 is counting down and the value of the number stored in register 100 is positive, the X-1 bits other than the sign bit directly indicate the number timer_out of clock cycles that remain until the number stored in register 100 changes sign, or, in other words, until circuit 1 has finished counting down for val_prog clock cycles.

Furthermore, when the value of the number stored in register 100 is negative but still greater than valmin, the X-1 bits other than the sign bit indicate the number timer_out of clock cycles that have elapsed since the number stored in the register reached zero. In other words, when the value of the number stored in register 100 is negative, still greater than valmin, and is decremented by one at each clock cycle, the X-1 bits other than the sign bit indicate the number timer_out of clock cycles that have elapsed since circuit 1 finished counting down val_prog clock cycles.

Preferably, when circuit 1 receives a request to write a value val_prog into register 100 while the current value of the number stored in register 100 is positive and less than valmax, writing this value val_prog into register 100 has priority over decrementing the current value of the number stored in register 100. This allows programming timer circuit 1 with a new value val_prog even if timer circuit 1 is already enabled and currently counting down.

An advantage of circuit 1 is that programming the circuit and starting the countdown are accomplished in a single step of writing into register 100. These steps are implemented in only one clock cycle. Thus, it is not necessary to first program circuit 1 with a programming value val_prog and then send a further control signal to circuit 1 to begin the countdown.

Compared to known countdown timer circuits, circuit 1 is simpler as it comprises only one register of X bits.

Furthermore, although not detailed here, register 100 of timer circuit 1 can be accessed for reading. When a read access to circuit 1 is performed, circuit 1 provides as a response the X bits stored in register 100. By doing this, the circuit that has performed the read access receives the information of whether timer circuit 1 is disabled (when register 100 stores the valmax value), or whether timer circuit 1 is counting down and has not yet reached zero (when register 100 stores a positive integer less than valmax), or whether timer circuit 1 is counting down and has already passed zero (when register 100 stores a negative integer greater than valmin), or whether the number of clock cycles that has elapsed since timer circuit 1 reached zero is greater than valmax (when register 100 stores the valmin value).

FIG. 2 illustrates, by a flow chart, the operation of the countdown timer circuit of FIG. 1.

The steps illustrated in FIG. 2 are implemented at each clock cycle, or, in other words, at the beginning of each period of the signal clk. In other words, the operation of circuit 1 illustrated by the flowchart of FIG. 2 is implemented once at each clock cycle.

At step 200 ("WRITE?" in FIG. 2), circuit 1 checks whether a request for writing, or programming, a value val_prog is received.

If this is the case (branch Y of block 200), step 200 is followed by step 202 ("PROG REG" in FIG. 2).

At step 202, circuit 1 writes the received programming value val_prog into register 100. In other words, at step 202, circuit 1 updates the value of the number stored in register 100 with the value val_prog received in a write request.

Step 202 is followed by step 204 ("END" in FIG. 2). In step 204, circuit 1 does nothing. Circuit 1 remains in step 204 until the beginning of the next clock cycle.

At step 200, if no write request is received by circuit 1 (branch N of block 200), step 200 is followed by step 206 ("MAX OR MIN?" in FIG. 2).

At step 206, circuit 1 checks whether the value of the number stored in register 100 is equal to either valmin or valmax.

If this is the case (branch Y of block 206), step 200 is followed by step 204.

However, if this is not the case (branch N of block 206), step 206 is followed by step 208 ("DEC REG" in FIG. 2).

At step 208, circuit 1 decrements by one the value of the number stored in register 100. Step 208 is followed by step 204.

Although not explicitly shown in FIG. 2, in practice, each update of the value of the number stored in register 100 is done in synchronism with the clock signal clk. Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove.

1. A timer circuit, comprising:
a register configured to be synchronized to a clock signal and to store a number as an X-bit signed integer, X being greater than two;
wherein the timer circuit is configured, at each cycle of the clock signal:
to decrement by one the number stored in the register if the number has a value different from a maximal value that the number is able to take and from a minimal value that the number is able to take; and
to keep unchanged the number stored in the register if the number has a value equal to the maximal value or to the minimal value.

2. The timer circuit of claim 1, wherein the maximal value is equal to 2^{X-1}-1 and the minimal value is equal to -2^{X-1}.

3. The timer circuit of claim 1, wherein the timer circuit is configured, when receiving a write request of a programming value, to write the programming value in the register.

4. The timer circuit of claim 3, wherein the timer circuit is configured so that writing the programming value in the register has priority over the decrement of the number stored in the register.

5. The timer circuit of claim 1, wherein a bit indicating a sign of the number stored in the register implements an alarm signal.

6. The timer circuit of claim 1, wherein X is equal to 32.

7. The timer circuit of claim 1, wherein the register is configured to store only X bits.

8. The timer circuit of claim 1, wherein the timer circuit comprises no further register.

9. The timer circuit of claim 1, wherein the timer circuit is configured so that the number stored in the register has the maximal value when the timer circuit is reset.

10. The timer circuit of claim 1, wherein the timer circuit is a countdown timer circuit.

11. The timer circuit of claim 1, wherein the register of the timer circuit is configured to be read.

12. A method of operating a timer circuit, the method comprising:
synchronizing a register to a clock signal, wherein the register is configured to store a number as an X-bit signed integer, where X is greater than two; and
at each cycle of the clock signal:
decrementing by one the number stored in the register if the number has a value different from a maximum value and a minimum value that the number is able to take; and
maintaining the number stored in the register unchanged if the number has a value equal to the maximum value or the minimum value.

13. The method of claim 12, further comprising:
receiving a write request for a programming value; and
writing the programming value into the register, wherein writing the programming value has priority over decrementing the number stored in the register.

14. The method of claim 12, wherein the maximum value is equal to 2^{X-1} - 1 and the minimum value is equal to -2^{X-1}.

15. The method of claim 12, further comprising using a bit indicating the sign of the number stored in the register as an alarm signal.

16. The method of claim 12, wherein X is equal to 32.

17. The method of claim 12, wherein the register is configured to store only X bits.

18. The method of claim 12, wherein the timer circuit comprises no additional registers.

19. The method of claim 12, further comprising resetting the timer circuit, wherein the number stored in the register is set to the maximum value upon reset.

20. The method of claim 12, further comprising reading the value stored in the register to determine a state of the timer circuit, including whether the timer circuit is disabled, counting down and has not yet reached zero, or counting down and has already passed zero.
